(19) United States
(12) Patent Application Publication
(10) Pub. No.: US 2015/0053956 A1
(43) Pub. Date: Feb. 26, 2015

(54) ORGANIC ELECTROLUMINESCENCE DISPLAY DEVICE

(71) Applicant: Japan Display Inc., Tokyo (JP)

(72) Inventor: Toshihiro SATO, Tokyo (JP)

(21) Appl. No.: 14/463,704

(22) Filed: Aug. 20, 2014

(30) Foreign Application Priority Data
Aug. 21, 2013 (JP) 2013-171619

(51) Int. Cl. H01L 51/52; H01L 27/32

(52) U.S. Cl. CPC H01L 51/5246; H01L 27/3244; H01L 27/322; H01L 51/5284; H01L 51/525
USPC 257/40

(57) ABSTRACT

An organic EL display device includes: a circuit substrate formed of a plurality of layers including an organic EL layer; a counter substrate facing and spaced from a surface of the circuit substrate on which the organic EL layer is provided; a seal provided around the organic EL layer between the circuit substrate and the counter substrate; a filler filling a space surrounded by the circuit substrate, the counter substrate, and the seal; and a color filter layer and a black matrix layer stacked on the counter substrate on the side of the space. The seal includes a layer of the same material as at least one of the color filter layer and the black matrix layer.

### CROSS-REFERENCE TO RELATED APPLICATION

The present application claims priority from Japanese application JP2013-171619 filed on Aug. 21, 2013, the content of which is hereby incorporated by reference into this application.

### BACKGROUND OF THE INVENTION

1. Field of the Invention

The present invention relates to an organic electroluminescence display device.

2. Description of the Related Art

In an organic electroluminescence display device, a counter substrate is bonded to a TFT (Thin Film Transistor) substrate so as to face an OLED (Organic Light-Emitting Diode) element portion located on the TFT substrate. In this structure, for ensuring the reliability of the OLED element portion formed on the TFT substrate, a sealing film is formed of SiN or the like on the OLED element, and further, for the purpose of reducing the loss of light due to internal reflection, the counter substrate is bonded via a filler to the TFT substrate (JP 2006-338946 A and JP 2005-302740 A).

### SUMMARY OF THE INVENTION

The filler fills a sealing space surrounded by a seal. Specifically, the seal is provided at the peripheral edge portion of the TFT substrate in the shape of a dam, the filler is dropped inside the dam, and the counter substrate is bonded to the TFT substrate. Since the formation of the dam is performed by a dispenser, dedicated facility and material are required, and also, it is difficult to form a high-precision pattern shape using the dispenser.

It is an object of the invention to easily provide a seal in a high-precision pattern shape.

(1) An organic electroluminescence display device according to an aspect of the invention includes: a circuit substrate formed of a plurality of layers including an organic electroluminescence layer; a counter substrate facing and spaced from a surface of the circuit substrate on which the organic electroluminescence layer is provided; a seal provided around the organic electroluminescence layer between the circuit substrate and the counter substrate; a filler filling a space surrounded by the circuit substrate, the counter substrate, and the seal; and a color filter layer and a black matrix layer stacked on the counter substrate on the side of the space, wherein the seal includes a layer of the same material as at least one of the color filter layer and the black matrix layer. According to the aspect of the invention, since the seal can be formed simultaneously with at least one of the color filter layer and the black matrix layer, the seal can be easily provided in a high-precision pattern shape.

(2) In the organic electroluminescence display device according to (1), the color filter layer may include colored layers of a plurality of colors, the seal may include a stacked structure of at least two layers, and the stacked structure of at least two layers may be formed of the same materials as the colored layers of at least two colors.

(3) In the organic electroluminescence display device according to (1) or (2), the organic electroluminescence display device may further include an overcoat layer provided on the counter substrate so as to cover the color filter layer and the black matrix layer, and the seal may further include a layer formed of the same material as the overcoat layer.

(4) In the organic electroluminescence display device according to (3), the layer formed of the same material as the overcoat layer may be formed thicker than the overcoat layer.

(5) In the organic electroluminescence display device according to any one of (1) to (4), the organic electroluminescence display device may further include a reinforcing layer formed of a resin provided outside the seal.

(6) In the organic electroluminescence display device according to any one of (1) to (5), the seal may be formed so as to have a cut.

(7) In the organic electroluminescence display device according to any one of (1) to (6), the organic electroluminescence display device may further include a spacer layer maintaining a gap to form the space between the circuit substrate and the counter substrate, and the seal may further include a layer formed of the same material as the spacer layer.

### BRIEF DESCRIPTION OF THE DRAWINGS

FIG. 1 is a plan view showing an organic electroluminescence display device according to an embodiment of the invention.

FIG. 2 is a cross-sectional view of the organic electroluminescence display device shown in FIG. 1, taken along the line II-II.

FIG. 3 is a diagram showing an organic electroluminescence display device according to Modified Example 1 of the embodiment.

FIG. 4 is a diagram showing an organic electroluminescence display device according to Modified Example 2 of the embodiment.

FIG. 5 is a diagram showing an organic electroluminescence display device according to Modified Example 3 of the embodiment.

FIG. 6 is a diagram showing an organic electroluminescence display device according to Modified Example 4 of the embodiment.

FIG. 7 is a diagram showing an organic electroluminescence display device according to Modified Example 5 of the embodiment.

FIG. 8 is a diagram showing an organic electroluminescence display device according to Modified Example 6 of the embodiment.

### DETAILED DESCRIPTION OF THE INVENTION

Hereinafter, an embodiment of the invention will be described with reference to the drawings.

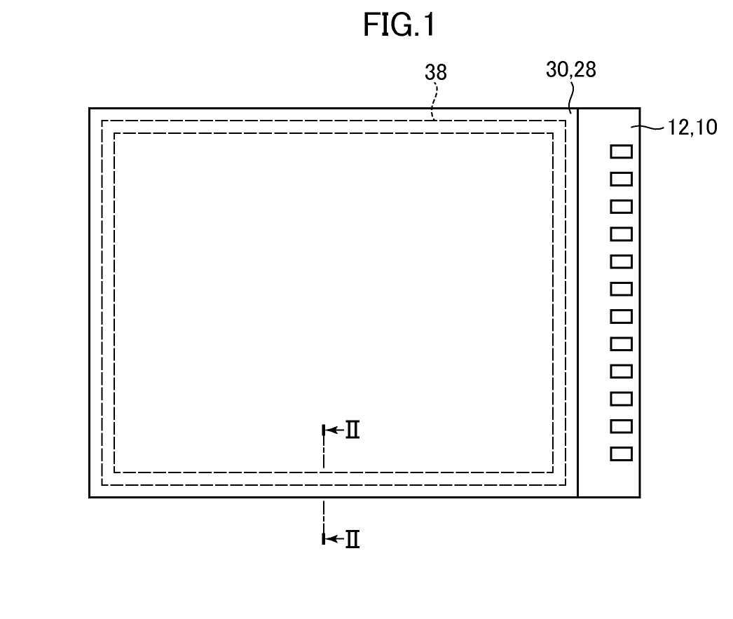

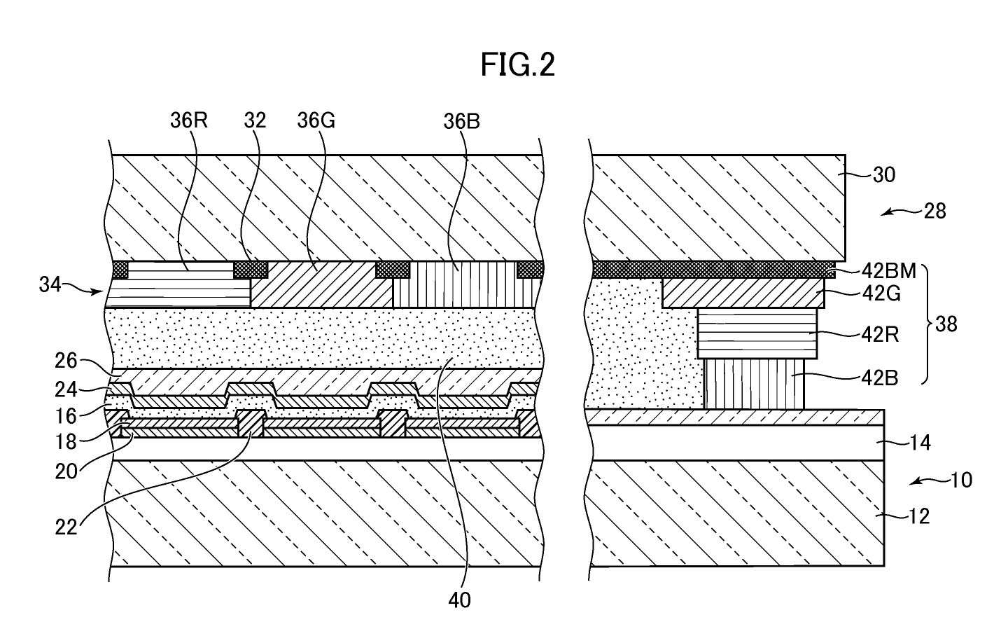

FIG. 1 is a plan view showing an organic electroluminescence display device according to the embodiment of the invention. FIG. 2 is a cross-sectional view of the organic electroluminescence display device shown in FIG. 1, taken along the line II-II.

The organic electroluminescence display device can be used for a television receiver, a monitor for a personal computer, a notebook personal computer, a PDA (Personal Digital Assistant), a mobile phone, a digital still camera, a digital video camcorder, a monitor for a car navigation system, and the like.

The organic electroluminescence display device includes a circuit substrate 10. The circuit substrate 10 is formed of a plurality of layers. One of the plurality of layers is a first substrate 12 formed of glass or the like. On the first substrate 12, a circuit layer 14 including a circuit of thin film transistors (not shown) is formed. At least one of the plurality of layers is an organic electroluminescence layer 16.

A lower electrode 18 (for example, an anode serving as a pixel electrode) is formed so as to be connected to a source electrode (or a drain electrode) of the thin film transistor (not shown). A reflective layer 20 that reflects light is located below the lower electrode 18. A bank layer 22 formed of an insulator is formed so as to expose a portion of the lower electrode 18. The organic electroluminescence layer 16 is formed so as to be in contact with the lower electrode 18 in the opening of the bank layer 22. The organic electroluminescence layer 16 includes at least a light-emitting layer, and a structure in which, for example, a hole injection layer, a hole transport layer, a light-emitting layer, an electron transport layer, and an electron injection layer are stacked in this order from the lower electrode 18 is known. On the organic electroluminescence layer 16, an upper electrode 24 (for example, a cathode serving as a common electrode) is formed. The organic electroluminescence layer 16 is covered with a sealing layer 26 formed of, for example, an inorganic material (for example, SiN, SiO, or SiON) or the like. The organic electroluminescence display device includes a counter substrate 28. The counter substrate 28 is spaced from the circuit substrate 10 and faces a surface of the circuit substrate 10 on which the organic electroluminescence layer 16 is provided. The counter substrate 28 is formed of a plurality of layers. One of the plurality of layers is a second substrate 30 formed of glass or the like.

A black matrix layer 32 and a color filter layer 34 are stacked on the counter substrate 28 on the side of a space formed between the counter substrate 28 and the circuit substrate 10. The black matrix layer 32 is formed on the second substrate 30. Moreover, the color filter layer 34 is formed on the second substrate 30. The color filter layer 34 includes colored layers 36R, 36G, and 36B of a plurality of colors (for example, red, green, and blue). The color filter layer 34 partially overlaps the black matrix layer 32. Since the color filter layer 34 is used, the organic electroluminescence layer 16 emits white light in this example.

The organic electroluminescence display device includes a seal 38 provided around the organic electroluminescence layer 16 between the circuit substrate 10 and the counter substrate 28. The organic electroluminescence display device includes a filler 40 filling a space surrounded by the circuit substrate 10, the counter substrate 28, and the seal 38. The filler 40 is formed of a light-transmissive (for example, transparent) resin. The loss of light due to internal reflection is reduced by the filler 40.

The seal 38 includes a stacked structure of at least two layers. The seal 38 includes a layer 42BM, 42G, 42R, or 42B of the same material as at least one of the color filter layer 34 and the black matrix layer 32. In the example of FIG. 2, a plurality of the layers 42BM, 42G, 42R, and 42B formed of the same materials as the black matrix layer 32 and the colored layers 36R, 36G, and 36B of all colors are stacked to constitute the seal 38. The stacked structure of at least two (in this example, three) layers 42G, 42R, and 42B of the seal 38 is formed of the same materials as the colored layers 36R, 36G, and 36B of at least two (in this example, three) different colors.

The seal 38 can be formed simultaneously with the color filter layer 34 and the black matrix layer 32. For example, the black matrix layer 32 and the layer 42BM constituting a portion of the seal 38 are integrally formed. When the black matrix layer 32 is formed of metal, a metal film (not shown) is formed on the second substrate 30, and etching is performed on the metal film as a black matrix layer according to the shape of an etching mask (not shown). The etching mask has a shape corresponding to the black matrix layer 32 and the layer 42BM constituting a portion of the seal 38. When the etching mask is precisely formed, the layer 42BM as a portion of the seal 38 can be formed in a high-precision pattern shape. When the black matrix layer 32 is formed of a resin, the black matrix layer 32 is formed by patterning a photoresist layer (not shown) using photolithography. An exposure mask (not shown) used in photolithography has a shape corresponding to the black matrix layer 32 and the layer 42BM constituting a portion of the seal 38. When the exposure mask is precisely formed, the layer 42BM as a portion of the seal 38 can be formed in a high-precision pattern shape.

In the forming process of the color filter layer 34, the plurality of colored layers 36R, 36G, and 36B are separately formed. Each of the colored layers 36R, 36G, and 36B can be formed by patterning a photoresist layer using photolithography. In that case, in photolithography, an exposure mask (not shown) corresponding to the colored layer 36G and the layer 42G, an exposure mask (not shown) corresponding to the colored layer 36R and the layer 42R, and an exposure mask (not shown) corresponding to the colored layer 36B and the layer 42B are used. The layers 42G, 42R, and 42B constituting portions of the seal 38 are formed simultaneously with the corresponding colored layers 36R, 36G, and 36B, respectively. When the exposure masks are precisely formed, the layers 42G, 42R, and 42B as portions of the seal 38 can be formed in high-precision pattern shapes.

In the embodiment, the colored layers 36R, 36G, and 36B of the plurality of colors are formed one by one. In the example of FIG. 2, the green colored layer 36G, the red colored layer 36R, and the blue colored layer 36B are formed in this order. Hence, the green layer 42G, the red layer 42R, and the blue layer 42B are stacked in this order from the second substrate 30.

According to the embodiment, since the seal 38 can be formed simultaneously with at least one of the color filter layer 34 and the black matrix layer 32, the seal 38 can be easily provided in a high-precision pattern shape.

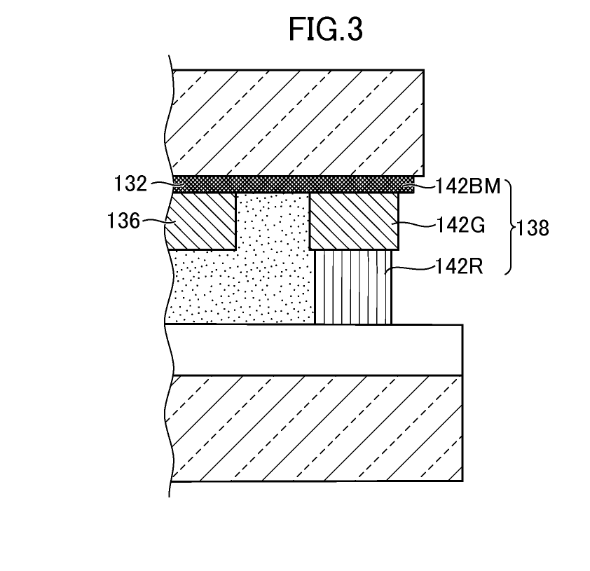

FIG. 3 is a diagram showing an organic electroluminescence display device according to Modified Example 1 of the embodiment. In this example, a seal 138 is composed of a plurality of layers 142BM, 142G, and 142R formed of the same materials as a black matrix layer 132 and a plurality of colored layers. It is not a colored layer 136 of all colors but a colored layer 136 of some of the colors (for example, green and red) that corresponds to the plurality of layers 142G and 142R constituting at least portions of the seal 138.

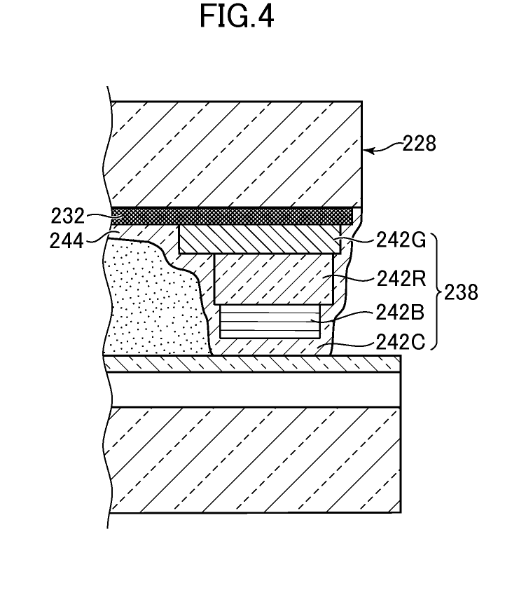

FIG. 4 is a diagram showing an organic electroluminescence display device according to Modified Example 2 of the embodiment. In this example, an overcoat layer 244 is provided on a counter substrate 228 so as to cover a color filter layer (not shown) and a black matrix layer 232. A seal 238 further includes a layer 242C formed of the same material as the overcoat layer 244. The overcoat layer 244 and the layer 242C formed of the same material as the overcoat layer 244 for constituting the seal 238 are continuously formed. The overcoat layer 244 is formed of a light-transmissive (for example, transparent) resin, and is superior in durability, strength, and barrier performance to colored layers. Since layers 242G, 242R, and 242B formed of the same materials as the colored layers are covered with the layer 242C formed of the same material as the overcoat layer 244, the reliability of the seal 238 is improved.

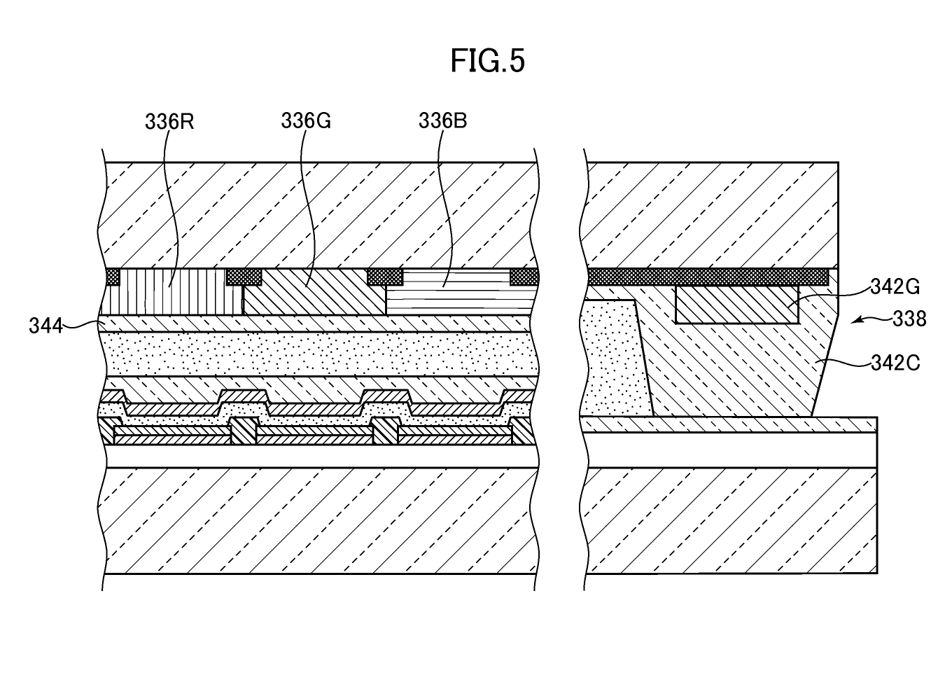

FIG. 5 is a diagram showing an organic electroluminescence display device according to Modified Example 3 of the embodiment. In this example, a layer 342C formed of the same material as an overcoat layer 344 is formed thicker than the overcoat layer 344. A seal 338 includes a layer 342G formed of the same material as a colored layer 336G, but does not include layers formed of the same materials as colored layers 336R and 336B. However, the layer 342C is formed thick, so that the seal 338 can be formed to have a required height.

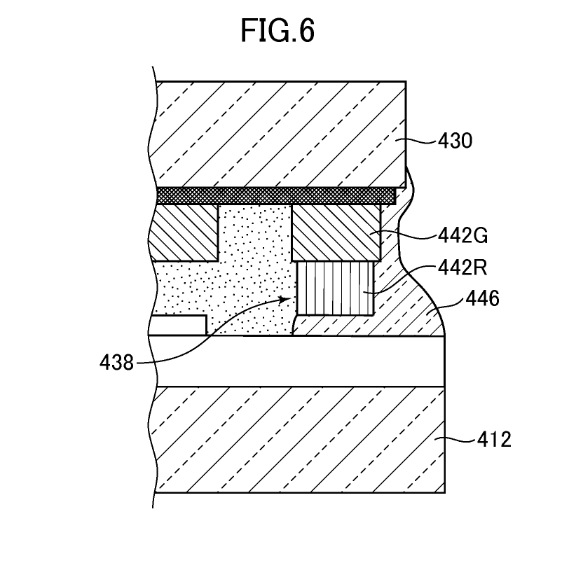

FIG. 6 is a diagram showing an organic electroluminescence display device according to Modified Example 4 of the embodiment. In this example, a reinforcing layer 446 formed of a resin provided outside a seal 438 is further included. The seal 438 is reinforced by the reinforcing layer 446. The seal 438 is provided over the entire peripheral edge portion of a second substrate 430, and corresponding to this, the reinforcing layer 446 is also provided over the entire peripheral edge portion of the second substrate 430. The reinforcing layer 446 protrudes from the second substrate 430. Since a portion of the reinforcing layer 446 overlaps layers 442G and 442R formed of the same materials as colored layers and constituting portions of the seal 438, the reinforcing layer 446 also constitutes a portion of the seal 438. Hence, the reinforcing layer 446 shown in FIG. 6 is formed before bonding a first substrate 412 and the second substrate 430 together. Alternatively, after bonding the first substrate 412 and the second substrate 430 together, the reinforcing layer 446 may be formed outside the seal 438. In that case, unlike the example of FIG. 6, the reinforcing layer 446 is not present between the seal 438 and the first substrate 412.

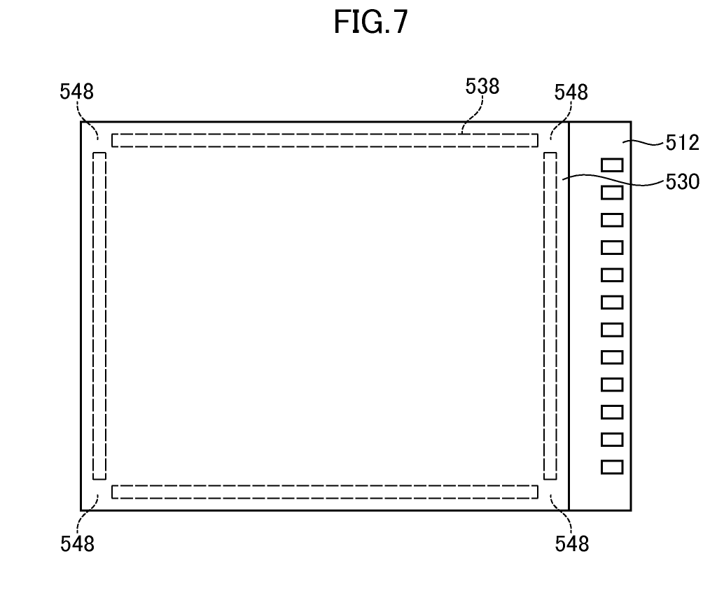

FIG. 7 is a diagram showing an organic electroluminescence display device according to Modified Example 5 of the embodiment. In this example, a seal 538 is formed so as to have cuts 548. According to this configuration, a filler leaks out from the cuts 548. Therefore, when the filler is dropped onto at least one of a first substrate 512 and a second substrate 530 and then a circuit substrate and a counter substrate are bonded together, an excessive filler or air bubbles can be discharged through the cuts 548. Hence, a layer of the filler with few air bubbles can be formed, so that the yield can be improved.

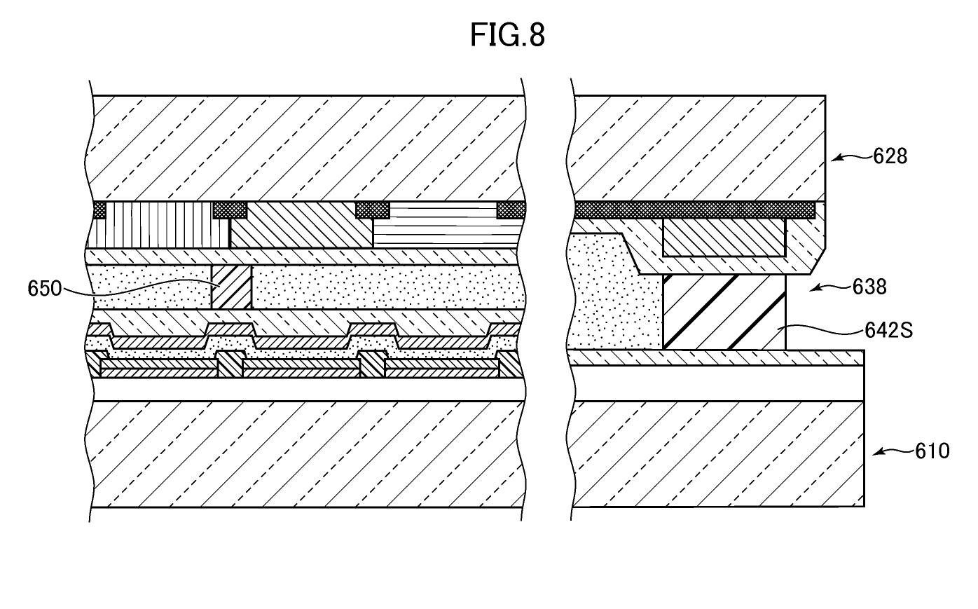

FIG. 8 is a diagram showing an organic electroluminescence display device according to Modified Example 6 of the embodiment. In this example, a spacer layer 650 is provided between a circuit substrate 610 and a counter substrate 628. With the spacer layer 650, a gap between the circuit substrate 610 and the counter substrate 628 is maintained to form a space therebetween. A seal 638 includes a layer 642S formed of the same material as the spacer layer 650. This example can be combined with the embodiment or any of the modified examples.

While there have been described what are at present considered to be certain embodiments of the invention, it will be understood that various modifications may be made thereto, and it is intended that the appended claims coverall such modifications as fall within the true spirit and scope of the invention.

What is claimed is:

1. An organic electroluminescence display device comprising:
a circuit substrate formed of a plurality of layers including an organic electroluminescence layer;
a counter substrate facing and spaced from a surface of the circuit substrate on which the organic electroluminescence layer is provided;
a seal provided around the organic electroluminescence layer between the circuit substrate and the counter substrate;
a filler filling a space surrounded by the circuit substrate, the counter substrate, and the seal; and
a color filter layer and a black matrix layer stacked on the counter substrate on the side of the space, wherein
the seal includes a layer of the same material as at least one of the color filter layer and the black matrix layer.

2. The organic electroluminescence display device according to claim 1, wherein
the color filter layer includes colored layers of a plurality of colors,
the seal includes a stacked structure of at least two layers, and
the stacked structure of at least two layers is formed of the same materials as the colored layers of at least two colors.

3. The organic electroluminescence display device according to claim 1, further comprising an overcoat layer provided on the counter substrate so as to cover the color filter layer and the black matrix layer, wherein
the seal further includes a layer formed of the same material as the overcoat layer.

4. The organic electroluminescence display device according to claim 3, wherein
the layer formed of the same material as the overcoat layer is formed thicker than the overcoat layer.

5. The organic electroluminescence display device according to claim 1, further comprising a reinforcing layer formed of a resin provided outside the seal.

6. The organic electroluminescence display device according to claim 1, wherein
the seal is formed so as to have a cut.

7. The organic electroluminescence display device according to claim 1, further comprising a spacer layer maintaining a gap to form the space between the circuit substrate and the counter substrate, wherein
the seal further includes a layer formed of the same material as the spacer layer.
